(19) United States
(12) Patent Application Publication
(10) Pub. No.: US 2025/0007467 A1
(43) Pub. Date: Jan. 2, 2025

(54) AMPLIFIER CIRCUIT

(71) Applicant: Murata Manufacturing Co., Ltd., Nagaokakyo-shi (JP)

(72) Inventor: Ikumi TOKUDA, Nagaokakyo-shi (JP)

(73) Assignee: Murata Manufacturing Co., Ltd., Nagaokakyo-shi (JP)

(21) Appl. No.: 18/749,675

(22) Filed: Jun. 21, 2024

(30) Foreign Application Priority Data
Jun. 28, 2023 (JP) 2023-105817

(51) Int. Cl. H03F 1/02

(52) U.S. Cl. CPC H03F 1/0288; H03F 2200/451; H03F 2200/541

(57) ABSTRACT

An amplifier circuit includes a carrier amplifier connected between a signal input terminal and a signal output terminal, a peak amplifier connected between the signal input terminal and the signal output terminal, a first phase shift circuit connected between the carrier amplifier or the peak amplifier and the signal output terminal, an auxiliary amplifier connected between the signal input terminal and the carrier amplifier, and a second phase shift circuit connected between the signal input terminal and the carrier amplifier.

### CROSS-REFERENCE TO RELATED APPLICATION

The present application claims priority to Japanese patent application JP 2023-105817, filed Jun. 28, 2023, the entire contents of which are incorporated herein by reference.

### BACKGROUND

In a Doherty amplifier circuit, when the power level of an input signal becomes high, the peak amplifier operates to adjust the load impedance of the output end of the carrier amplifier. This improves the efficiency and the linearity of the Doherty amplifier circuit.

### SUMMARY

An amplifier circuit according to an aspect of the present disclosure includes an input terminal and an output terminal; a carrier amplifier connected between the input terminal and the output terminal; a peak amplifier connected between the input terminal and the output terminal; a first phase shift circuit connected between the carrier amplifier and the output terminal or between the peak amplifier and the output terminal; an auxiliary amplifier connected between the input terminal and the carrier amplifier; and a second phase shift circuit that is connected between the input terminal and the carrier amplifier.

Also, an amplifier circuit according to an aspect of the present disclosure includes an input terminal and an output terminal; a carrier amplifier connected between the input terminal and the output terminal; a peak amplifier connected between the input terminal and the output terminal; a first phase shift circuit connected between an output end of the carrier amplifier and the output terminal; an auxiliary amplifier connected between the input terminal and an input end of the carrier amplifier; and a second phase shift circuit connected between the input end of the carrier amplifier and a connection point between the input terminal and an output end of the auxiliary amplifier.

Also, an amplifier circuit according to an aspect of the present disclosure includes an input terminal and an output terminal; a carrier amplifier connected between the input terminal and the output terminal; a peak amplifier connected between the input terminal and the output terminal; a first phase shift circuit and a second phase shift circuit; an auxiliary amplifier connected between the input terminal and an input end of the carrier amplifier; and a transformer including an input-side coil and an output-side coil. A first end of the first phase shift circuit is connected to an output end of the peak amplifier; a first end of the input-side coil is connected to an output end of the carrier amplifier; a second end of the input-side coil is connected to a second end of the first phase shift circuit; a first end of the output-side coil is connected to the output terminal; a second end of the output-side coil is connected to a ground; a first end of the second phase shift circuit is connected to a connection point between the input terminal and an output end of the auxiliary amplifier; and a second end of the second phase shift circuit is connected to the input end of the carrier amplifier.

### BRIEF DESCRIPTION OF THE DRAWINGS

FIG. 1 is a circuit diagram of an amplifier circuit, a radio frequency circuit, and a communication device according to a first example;

FIG. 2 is a circuit diagram of an amplifier circuit according to a comparative example;

FIG. 3 is a graph showing characteristics of the gain and the load impedance of each of the amplifier circuits according to the example and the comparative example;

FIG. 4 is a circuit diagram of an amplifier circuit, a radio frequency circuit, and a communication device according to a second example;

FIG. 5 is a circuit diagram of an amplifier circuit according to a third example;

FIG. 6 is a circuit diagram of an amplifier circuit according to a fourth example; and

FIG. 7 is a circuit diagram of an amplifier circuit according to a fifth example.

### DESCRIPTION OF THE EXEMPLARY EMBODIMENTS

In the case of the Doherty amplifier circuit, while the peak amplifier is in operation, a signal obtained by combining output signals of the carrier amplifier and the peak amplifier is output from the carrier amplifier. However, when the load impedance of the output end of the carrier amplifier is not ideal, a part of the output signal of the peak amplifier is not combined with the output signal of the carrier amplifier and may leak to the output terminal of the Doherty amplifier circuit. As a result, power efficiency of the Doherty amplifier circuit decreases, gain linearity is reduced, and signal distortion may occur.

The present disclosure is made to solve the above-described situation, and one aspect of the present disclosure is to provide a Doherty amplifier circuit that can improve power efficiency and reduce signal distortion.

The present disclosure makes it possible to provide a Doherty amplifier circuit that can improve power efficiency and reduce signal distortion.

Exemplary embodiments of the present disclosure are described below in detail. Each of the exemplary embodiments described below represents a general or specific example.

Values, shapes, materials, components, and layouts and connection configurations of the components described in the exemplary embodiments below are just examples and are not intended to limit the present disclosure. Among components described in the examples and the variations below, components not recited in independent claims are optional components. Also, the sizes or the ratios of sizes of components illustrated in the drawings are not necessarily accurate. In the drawings, the same reference number is assigned to substantially the same components, and overlapping descriptions of those components are omitted or simplified.

Also, in the descriptions below, terms such as “parallel” and “perpendicular” indicating relationships between elements, terms such as “rectangular” indicating shapes of elements, and numerical ranges do not only indicate their exact meanings but may also indicate substantially equivalent ranges that vary by, for example, about a few percent.

In circuit configurations of the present disclosure, “connected” not only indicates that circuit elements are directly connected to each other with a connection terminal and/or a wire conductor but also indicates that the circuit elements are electrically connected to each other via another circuit element. Also, “connected between A and B” indicates that a component is disposed between A and B and connected to both of A and B. Specifically, “connected between A and B” not only indicates that a component is connected in series with A and B in a path connecting A and B but also indicates that a component is connected in parallel with (in shunt connection with) A and B at a position between the path and a ground.

Furthermore, in the present disclosure, “signal path” indicates a transmission line that is constituted by, for example, a wire for transmitting a radio frequency signal, an electrode directly connected to the wire, and a terminal directly connected to the wire or the electrode.

In circuit connection configurations of the present disclosure, “component (element) A is disposed in series with path B” means that each of a signal input end and a signal output end of the component (element) A is connected to one of a wire, an electrode, and a terminal constituting the path B. Also, “multiple paths are connected in parallel with each other” means that ends of the multiple paths are connected to the same wire, electrode, or terminal.

### Exemplary Embodiment

### 1 Circuit Configurations of Amplifier Circuit 10, Radio Frequency Circuit 1, and Communication Device 4 According to First Example

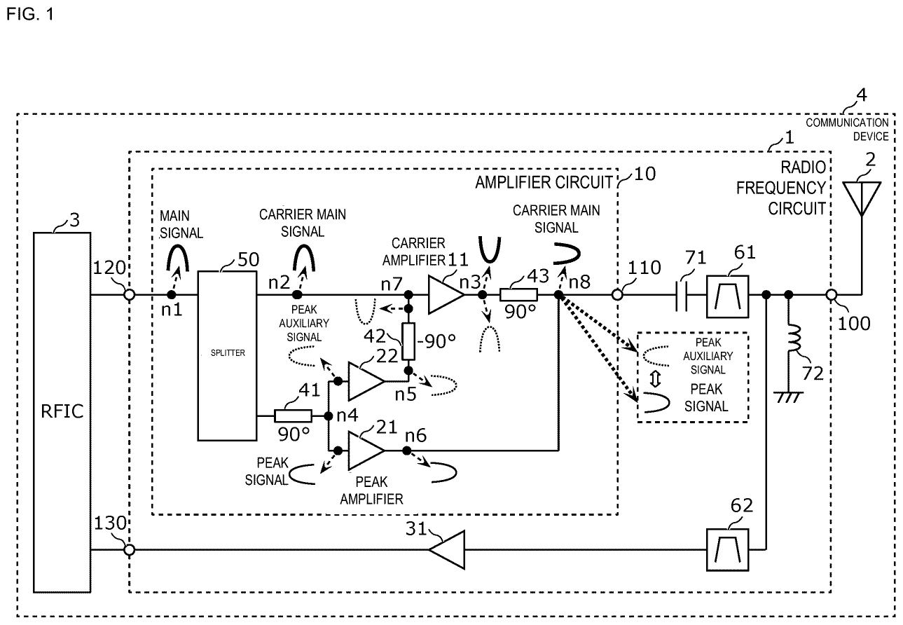

Circuit configurations of an amplifier circuit 10, a radio frequency circuit 1, and a communication device 4 according to a first example of the present exemplary embodiment are described with reference to FIG. 1. FIG. 1 is a circuit diagram of the amplifier circuit 10, the radio frequency circuit 1, and the communication device 4 according to the first example.

### 1.1 Circuit Configuration of Communication Device 4

First, a circuit configuration of the communication device 4 is described. As illustrated in FIG. 1, the communication device 4 according to the first example includes the radio frequency circuit 1, an antenna 2, and an RF signal processing circuit (RFIC) 3.

The radio frequency circuit 1 transmits radio frequency signals between the antenna 2 and the RFIC 3. The detailed circuit configuration of the radio frequency circuit 1 is described later.

The antenna 2 is connected to an antenna connection terminal 100 of the radio frequency circuit 1, transmits a radio frequency signal output from the radio frequency circuit 1, receives a radio frequency signal from the outside, and outputs the received radio frequency signal to the radio frequency circuit 1.

The RFIC 3 is an example of a signal processing circuit that processes a radio frequency signal and is connected to a signal input terminal 120 and a signal output terminal 130 of the radio frequency circuit 1. Specifically, the RFIC 3 performs signal processing, such as down converting, on a reception signal input via a reception path of the radio frequency circuit 1 and outputs a reception signal generated by the signal processing to a baseband signal processing circuit (BBIC) (not shown). Also, the RFIC 3 performs signal processing, such as up-converting, on a transmission signal input from the BBIC and outputs a transmission signal generated by the signal processing to a transmission path of the radio frequency circuit 1. The RFIC 3 includes a control unit that controls circuit components of the radio frequency circuit 1. Some or all of the functions of the control unit of the RFIC 3 may be provided outside of the RFIC 3 and may be implemented by, for example, a component in the BBIC or the radio frequency circuit 1.

The RFIC 3 also has a function of a control unit for controlling a power supply voltage and a bias voltage (or a bias current) supplied to each amplifier of the radio frequency circuit 1. Specifically, the RFIC 3 outputs a control signal to the radio frequency circuit 1. A power supply voltage and a bias voltage (or a bias current) controlled by the control signal are supplied to each amplifier of the radio frequency circuit 1.

In the communication device 4 according to this example, the antenna 2 is not an essential component.

### 1.2 Circuit Configuration of Radio Frequency Circuit 1

Next, a circuit configuration of the radio frequency circuit 1 is described. As illustrated in FIG. 1, the radio frequency circuit 1 includes the amplifier circuit 10, filters 61 and 62, a low-noise amplifier 31, a capacitor 71, an inductor 72, the antenna connection terminal 100, a signal output terminal 110, and the signal input terminal 120.

The filter 61 is connected between the signal output terminal 110 and the antenna connection terminal 100 and passes a transmission signal in a band A among transmission signals amplified by the amplifier circuit 10. The filter 62 is connected between the low-noise amplifier 31 and the antenna connection terminal 100 and passes a reception signal in a reception band corresponding to the band A among reception signals received by the antenna 2.

The filters 61 and 62 may constitute a duplexer that transmits and receives signals in the band A or may be implemented by a single filter that transmits signals according to time division duplex (TDD). When the filters 61 and 62 are implemented by a single filter for TDD, a switch for switching between transmission and reception is provided at least before or after the single filter.

The low-noise amplifier 31 is connected between the filter 62 and the signal output terminal 130, amplifies a reception signal in the band A, and outputs the amplified reception signal to the RFIC 3.

The capacitor 71 is a circuit element for impedance matching and is disposed in series between the signal output terminal 110 and the filter 61. The capacitor 71 may instead be connected between a ground and a path connecting the signal output terminal 110 to the filter 61 (i.e., shunt connection) or may be omitted.

The inductor 72 is a circuit element for impedance matching and is connected between the ground and a path connecting the filter 61 to the antenna connection terminal 100 (shunt connection). The inductor 72 may instead be disposed in series between the filter 61 and the antenna connection terminal 100 or may be omitted.

The radio frequency circuit 1 may also include a transmitter circuit that transmits a transmission signal in a band B different from the band A to the antenna 2 and a receiver circuit that transmits, to the RFIC 3, a reception signal in the band B received from the antenna 2. Furthermore, the radio frequency circuit 1 may be configured to transmit and receive radio frequency signals in three or more bands.

### 1.3 Circuit Configuration of Amplifier Circuit 10 According to First Example

Next, a circuit configuration of the amplifier circuit 10 is described in detail.

As illustrated in FIG. 1, the amplifier circuit 10 includes the signal input terminal 120, the signal output terminal 110, a carrier amplifier 11, a peak amplifier 21, an auxiliary amplifier 22, phase shift lines 41, 42, and 43, and a splitter 50.

The signal input terminal 120 is an example of an input terminal and is connected to the RFIC 3. The signal output terminal 110 is an example of an output terminal and is connected to the antenna connection terminal 100 via the capacitor 71 and the filter 61. Here, each of the signal input terminal 120, the signal output terminal 110, and the antenna connection terminal 100 may be a metal conductor, such as a metal electrode or a metal bump, or a point on a metal wire.

The carrier amplifier 11 amplifies a radio frequency signal that is input to the carrier amplifier 11. The carrier amplifier 11 is, for example, a class A (or class AB) amplifier circuit that can amplify signals of all power levels input to the carrier amplifier 11. Particularly, the carrier amplifier 11 can efficiently perform amplification in a low power region and a medium power region. The carrier amplifier 11 is, for example, an inverting amplifier that inverts the phase of an input signal and outputs a phase-inverted signal. The input end of the carrier amplifier 11 is connected to the signal input terminal 120 via the splitter 50, and the output end of the carrier amplifier 11 is connected to the signal output terminal 110 via the phase shift line 43.

The peak amplifier 21 amplifies a radio frequency signal input to the peak amplifier 21. The peak amplifier 21 is, for example, a class C amplifier circuit that can perform amplification in a region in which the power level of a signal input to the peak amplifier 21 is high. For example, a bias voltage lower than the bias voltage applied to the amplifier transistor of the carrier amplifier 11 is applied to the amplifier transistor of the peak amplifier 21. With this configuration, the output impedance decreases as the power level of a signal input to the peak amplifier 21 increases. This enables the peak amplifier 21 to perform low-distortion amplification in a high power region. The peak amplifier 21 is, for example, an inverting amplifier that inverts the phase of an input signal and outputs a phase-inverted signal. The input end of the peak amplifier 21 is connected to the signal input terminal 120 via the splitter 50 and the phase shift line 41, and the output end of the peak amplifier 21 is connected to the signal output terminal 110.

The auxiliary amplifier 22 amplifies a radio frequency signal input to the auxiliary amplifier 22. The auxiliary amplifier 22 is, for example, a class C amplifier circuit that can perform amplification in a region in which the power level of a signal input to the auxiliary amplifier 22 is high. For example, a bias voltage lower than the bias voltage applied to the amplifier transistor of the carrier amplifier 11 is applied to the amplifier transistor of the auxiliary amplifier 22. This enables the auxiliary amplifier 22 to perform low-distortion amplification in a high power region. The auxiliary amplifier 22 is, for example, an inverting amplifier that inverts the phase of an input signal and outputs a phase-inverted signal. The input end of the auxiliary amplifier 22 is connected to the signal input terminal 120 via the splitter 50 and the phase shift line 41, and the output end of the auxiliary amplifier 22 is connected to the input end of the carrier amplifier 11 via the phase shift line 42.

The bias voltage applied to the auxiliary amplifier 22 is preferably the same as the bias voltage applied to the peak amplifier 21. Furthermore, it is preferable that the power supply voltage applied to the auxiliary amplifier 22 is the same as the power supply voltage applied to the peak amplifier 21, and the operating point of the auxiliary amplifier 22 is the same as the operating point of the peak amplifier 21. This makes it possible to make the behavior of the output signal of the auxiliary amplifier 22 conform to the behavior of the output signal of the peak amplifier 21.

Each of the carrier amplifier 11, the peak amplifier 21, and the auxiliary amplifier 22 includes an amplifier transistor. The amplifier transistor is, for example, a bipolar transistor, such as a heterojunction bipolar transistor (HBT), or a field-effect transistor, such as a metal-oxide-semiconductor field effect transistor (MOSFET).

The amplifier transistor of the auxiliary amplifier 22 may be formed in a formation region of the amplifier transistor of the peak amplifier 21. Here, for example, when the amplifier transistor is a bipolar transistor, the formation region of the amplifier transistor is defined as a region in which the base, the emitter, and the collector are formed. Also, when the amplifier transistor of the auxiliary amplifier 22 is formed in the formation region of the amplifier transistor of the peak amplifier 21, it indicates that at least one of the base, the emitter, and the collector constituting the amplifier transistor of the auxiliary amplifier 22 shares at least a part of the base, the emitter, and the collector constituting the amplifier transistor of the peak amplifier 21. With this configuration, because the auxiliary amplifier 22 and the peak amplifier 21 share the amplifier transistor formation region, the behaviors of their output signals become the same, and the auxiliary amplifier 22 and the peak amplifier 21 operate as a pair.

The phase shift line 43 is an example of a first phase shift circuit and is, for example, a quarter wavelength transmission line. The phase shift line 43 delays the phase of a radio frequency signal input from its first end by 90° (a quarter wavelength) and outputs the phased-delayed radio frequency signal from its second end. The phase shift line 43 (the first phase shift circuit) does not have to be in the form of a phase shift line. For example, the phase shift line 43 may be an inductor, or a low pass filter including an inductor and a capacitor, that is disposed in series in a path connecting the carrier amplifier 11 to the signal output terminal 110. The first end of the phase shift line 43 is connected to the output end of the carrier amplifier 11, and the second end of the phase shift line 43 is connected to a connection point between the output end of the peak amplifier 21 and the signal output terminal 110.

The phase shift line 41 is an example of a third phase shift circuit and is, for example, a quarter wavelength transmission line. The phase shift line 41 delays the phase of a radio frequency signal input from its first end by 90° (a quarter wavelength) and outputs the phase-delayed radio frequency signal from its second end. The phase shift line 41 (the third phase shift circuit) does not have to be in the form of a phase shift line. For example, the phase shift line 41 may be an inductor, or a low pass filter including an inductor and a capacitor, that is disposed in series in a path connecting the splitter 50 to the peak amplifier 21 and the auxiliary amplifier 22. The first end of the phase shift line 41 is connected to the signal input terminal 120 via the splitter 50, and the second end of the phase shift line 41 is connected to the input end of the peak amplifier 21 and the input end of the auxiliary amplifier 22.

The phase shift line 42 is an example of a fourth phase shift circuit, advances the phase of a radio frequency signal input from its first end by 90° (a quarter wavelength) (or delays the radio frequency signal by 270°), and outputs the phase-advanced radio frequency signal from its second end. The phase shift line 42 (the fourth phase shift circuit) does not have to be in the form of a phase shift line and may be, for example, a capacitor, or a high-pass filter including a capacitor and an inductor, that is disposed in series in a path connecting the output end of the auxiliary amplifier 22 to the input end of the carrier amplifier 11. The first end of the phase shift line 42 is connected to the output end of the auxiliary amplifier 22, and the second end of the phase shift line 42 is connected to the input end of the carrier amplifier 11.

The phase shift lines 41 and 42 constitute a second phase shift circuit and are connected between the signal input terminal 120 and the input end of the carrier amplifier 11. With the above configuration, the phase shift lines 41 and 42 (the second phase shift circuit) can invert the phase of the output signal of the auxiliary amplifier 22 at the signal output terminal 110 with respect to the phase of the output signal of the peak amplifier 21 at the signal output terminal 110.

Each of the phase shift lines 41 and 43 is not necessarily configured to delay the phase of an input radio frequency signal in the band A exactly by 90° and may be any type of circuit that delays the phase of an input radio frequency signal in the band A by a degree within 90°±20°. Also, the phase shift line 42 is not necessarily configured to advance the phase of an input radio frequency signal in the band A exactly by 90° and may be any type of circuit that advances the phase of an input radio frequency signal in the band A by a degree within 90°±20°.

The splitter 50 is an example of a power splitter and is connected between the signal input terminal 120 and the input ends of the carrier amplifier 11, the peak amplifier 21, and the auxiliary amplifier 22. The splitter 50 includes a first terminal, a second terminal, and a third terminal. The splitter 50 distributes the power of a radio frequency signal input to the first terminal between two radio frequency signals at a predetermined distribution ratio, outputs one of the two radio frequency signals from the second terminal, and outputs the other one of two the radio frequency signals from the third terminal. The first terminal is connected to the signal input terminal 120, the second terminal is connected to the input end of the carrier amplifier 11, and the third terminal is connected to the first end of the phase shift line 41.

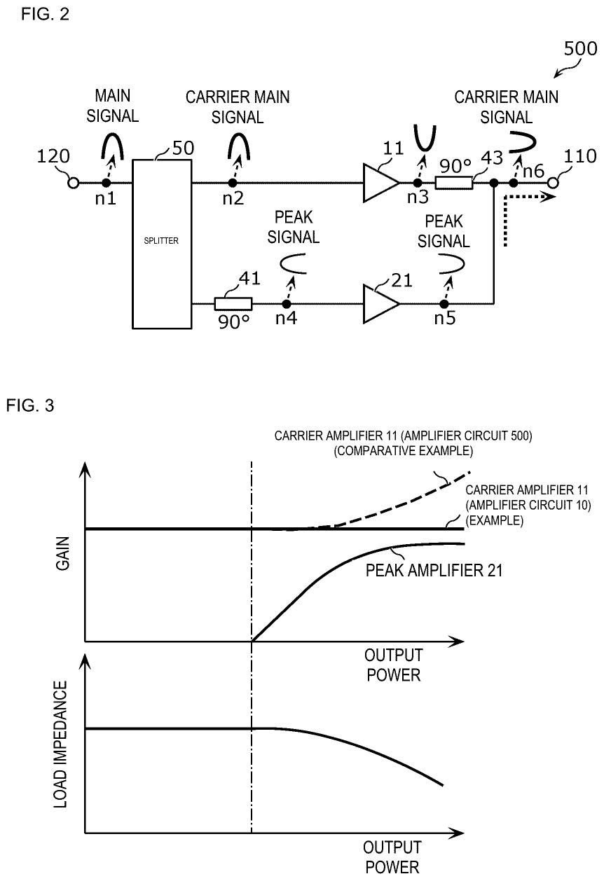

Next, an operation of a Doherty amplifier circuit including a carrier amplifier and a peak amplifier is described with reference to an amplifier circuit 500 according to a comparative example illustrated in FIG. 2.

A Doherty amplifier circuit achieves high efficiency by using multiple amplifiers as a carrier amplifier and a peak amplifier. The carrier amplifier in the Doherty amplifier circuit operates regardless of whether the power of a radio frequency signal (input) is low or high. The peak amplifier in the Doherty amplifier circuit operates primarily when the power of a radio frequency signal (input) is high. Accordingly, when the input power of a radio frequency signal is low, the radio frequency signal is amplified primarily by the carrier amplifier; and when the input power of a radio frequency signal is high, the radio frequency signal is amplified by the carrier amplifier and the peak amplifier, and amplified radio frequency signals are combined. With this operation, in the Doherty amplifier circuit, the load impedance seen from the carrier amplifier increases in the low output power region, and the efficiency at the low output power improves. Also, the load impedance seen from the carrier amplifier decreases in the high output power region, and the linearity at the high output power improves.

FIG. 2 is a circuit diagram of the amplifier circuit 500 according to the comparative example. The amplifier circuit 500 illustrated in FIG. 2 includes a signal input terminal 120, a signal output terminal 110, a carrier amplifier 11, a peak amplifier 21, phase shift lines 41 and 43, and a splitter 50. The amplifier circuit 500 according to the comparative example differs from the amplifier circuit 10 according to the first example in that the auxiliary amplifier 22 and the phase shift line 42 are not provided.

When the carrier amplifier 11 and the peak amplifier 21 are in operation (ON) (when a large signal is input), the load impedance of the carrier amplifier 11 is converted by the phase shift line 43 and becomes smaller than the load impedance of the carrier amplifier 11 observed when the carrier amplifier 11 is in operation (ON) and the peak amplifier 21 is not in operation (OFF) (when a small signal is input). Thus, when a large signal is input, the carrier amplifier 11 and the peak amplifier 21 operate, and a high power signal can be output.

When the carrier amplifier 11 is in operation (ON) and the peak amplifier 21 is not in operation (OFF) (when a small signal is input), the load impedance of the peak amplifier 21 becomes open-circuited, and the load impedance of the carrier amplifier 11 observed when a small signal is input becomes higher than that observed when a large signal is input. Thus, when a small signal is input, the load impedance of the carrier amplifier 11 increases, and the amplifier circuit 500 can operate highly efficiently.

However, when the carrier amplifier 11 and the peak amplifier 21 are in operation (when a large signal is input), because the carrier amplifier 11 has finite impedance and does not have ideal impedance, a part of the output signal of the peak amplifier 21 is not combined with the output signal of the carrier amplifier 11 and may leak to the signal output terminal 110 by itself. This may reduce the power efficiency of the amplifier circuit 500. Also, this may reduce gain linearity and thereby cause signal distortion.

In contrast, in the amplifier circuit 10 according to this example, because a path having the auxiliary amplifier 22 and the phase shift line 42 is provided, a signal (a peak signal) leaking directly from the peak amplifier 21 to the signal output terminal 110 is offset by a signal (a peak auxiliary signal) transmitted through the path. This in turn makes it possible to reduce the distortion of an output signal resulting from the operation of the peak amplifier 21.

A state of the amplifier circuit 10 according to this example is described in detail below with reference to FIG. 1.

As illustrated in FIG. 1, a radio frequency main signal is first input from the signal input terminal 120. Here, it is assumed that the phase of the radio frequency main signal is 0° at a node n1 on a path connecting the signal input terminal 120 to the splitter 50. It is also assumed that the power of the radio frequency main signal is distributed by the splitter 50 to a carrier main signal output to the carrier amplifier 11 and a peak signal and a peak auxiliary signal output to the peak amplifier 21 and the auxiliary amplifier 22. At a node n2 on a path connecting the splitter 50 to the carrier amplifier 11, the phase of the carrier main signal is unchanged at 0°. On the other hand, at a node n4 on a path connecting the phase shift line 41 to the peak amplifier 21 and the auxiliary amplifier 22, the phases of the peak signal and the peak auxiliary signal are delayed by 90° by the phase shift line 41 to become −90°.

Next, the phase of the carrier main signal is inverted by the carrier amplifier 11 to become −180° at a node n3 on a path connecting the output end of the carrier amplifier 11 to the phase shift line 43. On the other hand, the phase of the peak signal is inverted by the peak amplifier 21 to become −270° at a node n6 corresponding to the output end of the peak amplifier 21, and is −270° at a node n8 connecting the output end of the peak amplifier 21 to the phase shift line 43. Also, the phase of the peak auxiliary signal is inverted by the auxiliary amplifier 22 to become −270° at a node n5 corresponding to the output end of the auxiliary amplifier 22, and is advanced by 90° by the phase shift line 42 to become −180° at a node n7 corresponding to the input end of the carrier amplifier 11. Furthermore, the phase of the peak auxiliary signal is inverted by the carrier amplifier 11 to become 0° at the node n3 and is delayed by 90° by the phase shift line 43 to become −90° at the node n8. Here, because the phases of the peak signal and the peak auxiliary signal are opposite to each other at the node n8, the peak signal and the peak auxiliary signal substantially offset each other at the node n8.

This makes it possible to prevent a part of the output signal of the peak amplifier 21 from leaking to the signal output terminal 110 by itself.

Here, the gain of the auxiliary amplifier 22 is determined such that the amplitudes of the peak signal and the peak auxiliary signal become substantially the same at the node n8. In this example, the gain of the auxiliary amplifier 22 is preferably lower than the gain of the peak amplifier 21. This makes it possible to make the amplitude of the peak signal reaching the node n8 after being amplified by the peak amplifier 21 substantially the same as the amplitude of the peak auxiliary signal reaching the node n8 after being amplified by the auxiliary amplifier 22 and the carrier amplifier 11.

Also, the amplifier circuit 10 may further include an attenuator connected between the output end of the auxiliary amplifier 22 and a connection point between the input end of the carrier amplifier 11 and the phase shift line 42. This makes it possible to adjust the amplitude of the peak auxiliary signal. The attenuator may be configured such that its attenuation rate is variable according to the power and the frequency of a radio frequency signal input to the amplifier circuit 10.

FIG. 3 is a graph showing characteristics of the gain and the load impedance of each of the amplifier circuits according to the first example and the comparative example. The upper part of FIG. 3 shows the gains of the carrier amplifier 11 and the peak amplifier 21 in relation to the output power of the amplifier circuits. The lower part of FIG. 3 shows the load impedance at the output end of the carrier amplifier 11.

As shown in FIG. 3, the peak amplifier 21 is turned on in a region in which the output power of each amplifier circuit is high. When the peak amplifier 21 is turned on, the load impedance of the carrier amplifier 11 decreases, and the carrier amplifier 11 can output a high power signal.

Also, in the amplifier circuit 500 according to the comparative example, because the output signal of the peak amplifier 21 leaks to the signal output terminal 110 by itself, the gain of the amplifier circuit 500 increases as the output power increases. As a result, gain linearity is reduced, and signal distortion increases.

In contrast, with the amplifier circuit 10 according to this example, it is possible to prevent the output signal of the peak amplifier 21 from leaking to the signal output terminal 110 by itself, and the gain of the amplifier circuit 10 becomes substantially the same as the gain of the carrier amplifier 11. This in turn makes it possible to keep the gain constant and thereby makes it possible to reduce signal distortion. Thus, it is possible to provide the amplifier circuit 10 having improved power efficiency and configured to improve gain linearity and reduce signal distortion.

In the amplifier circuit 10 according to this example, the first end of the phase shift line 42 may be connected to the output end of the auxiliary amplifier 22, and the second end of the phase shift line 42 may be connected to the output end of the carrier amplifier 11. That is, the second phase shift circuit constituted by the third phase shift circuit and the fourth phase shift circuit may be connected between the signal input terminal 120 and the output end of the carrier amplifier 11. In this case, because the peak auxiliary signal does not pass through the carrier amplifier 11 and merges with the carrier main signal at the output end of the carrier amplifier 11, the phase shift line 42 needs to be configured to delay an input signal by 90°, and the gain of the auxiliary amplifier 22 needs to be set higher. This makes it possible to set the phases of the peak signal and the peak auxiliary signal to be opposite to each other at the node n8. As a result, the peak signal and the peak auxiliary signal substantially offset each other at the node n8. This in turn makes it possible to prevent the output signal of the peak amplifier 21 from leaking to the signal output terminal 110 by itself and thereby makes it possible to reduce signal distortion.

Also, in the amplifier circuit 10 according to this example, the peak amplifier 21 and the auxiliary amplifier 22 may be implemented by one peak amplifier and a power splitter connected to the output end of the peak amplifier.

### 2 Circuit Configurations of Amplifier Circuit 10A, Radio Frequency Circuit 1A, and Communication Device 4A According to Second Example

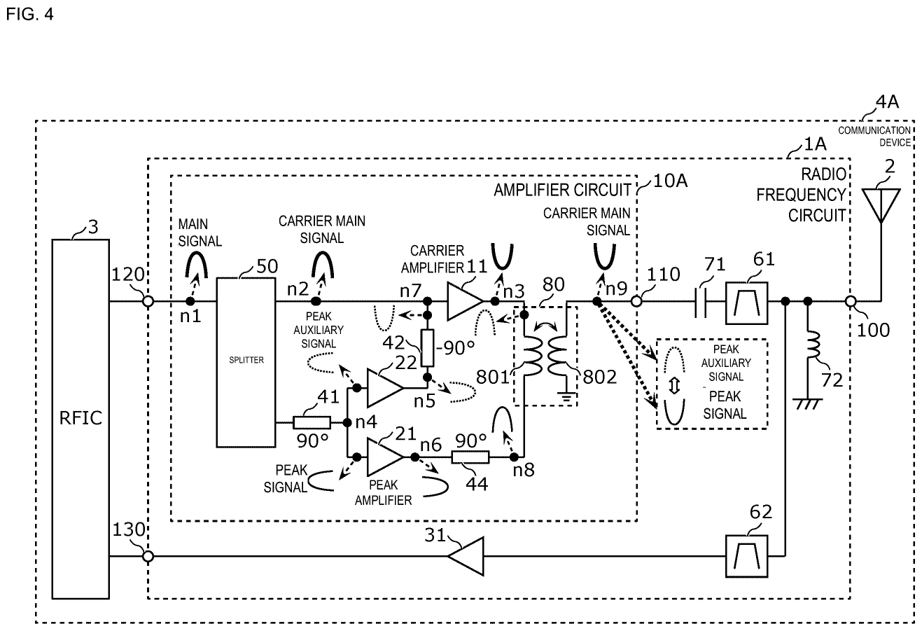

Circuit configurations of an amplifier circuit 10A, a radio frequency circuit 1A, and a communication device 4A according to a second example of the present exemplary embodiment are described with reference to FIG. 4. FIG. 4 is a circuit diagram of the amplifier circuit 10A, the radio frequency circuit 1A, and the communication device 4A according to the second example.

### 2.1 Circuit Configuration of Communication Device 4A

As illustrated in FIG. 4, the communication device 4A according to the second example includes the radio frequency circuit 1A, an antenna 2, and an RFIC 3. The communication device 4A according to this example differs from the communication device 4 according to the first example only in the configuration of the radio frequency circuit 1A. Also, the radio frequency circuit 1A according to this example differs from the radio frequency circuit 1 according to the first example only in the configuration of the amplifier circuit 10A. Therefore, the communication device 4A and the radio frequency circuit 1A according to this example are described below focusing on the configuration of the amplifier circuit 10A.

### 2.2 Circuit Configuration of Amplifier Circuit 10A

As illustrated in FIG. 4, the amplifier circuit 10A includes a signal input terminal 120, a signal output terminal 110, a carrier amplifier 11, a peak amplifier 21, an auxiliary amplifier 22, phase shift lines 41, 42 and 44, a splitter 50, and a transformer 80. The amplifier circuit 10A according to this example differs from the amplifier circuit 10 according to the first example in that a phase shift line 44 is provided in place of the phase shift line 43 and that the transformer 80 is added. Below, descriptions of configurations of the amplifier circuit 10A of this example identical to those of the amplifier circuit 10 of the first example are omitted, and different configurations are mainly described.

The input end of the carrier amplifier 11 is connected to the signal input terminal 120 via the splitter 50, and the output end of the carrier amplifier 11 is connected to the signal output terminal 110 via the transformer 80.

The input end of the peak amplifier 21 is connected to the signal input terminal 120 via the splitter 50 and the phase shift line 41, and the output end of the peak amplifier 21 is connected to the signal output terminal 110 via the transformer 80 and the phase shift line 44.

The input end of the auxiliary amplifier 22 is connected to the signal input terminal 120 via the splitter 50 and the phase shift line 41, and the output end of the auxiliary amplifier 22 is connected to the input end of the carrier amplifier 11 via the phase shift line 42.

The bias voltage applied to the auxiliary amplifier 22 is preferably the same as the bias voltage applied to the peak amplifier 21. Furthermore, it is preferable that the power supply voltage applied to the auxiliary amplifier 22 is the same as the power supply voltage applied to the peak amplifier 21, and the operating point of the auxiliary amplifier 22 is the same as the operating point of the peak amplifier 21. This makes it possible to make the behavior of the output signal of the auxiliary amplifier 22 conform to the behavior of the output signal of the peak amplifier 21.

The phase shift line 44 is an example of a first phase shift circuit and is, for example a quarter wavelength transmission line. The phase shift line 44 delays the phase of a radio frequency signal input from its first end by 90° (a quarter wavelength) and outputs the phase-delayed radio frequency signal from its second end. The phase shift line 44 (the first phase shift circuit) does not have to be in the form of a phase shift line. For example, the phase shift line 44 may be an inductor, or a low pass filter including an inductor and a capacitor, that is disposed in series in a path connecting the peak amplifier 21 to the signal output terminal 110. The first end of the phase shift line 44 is connected to the output end of the peak amplifier 21, and the second end of the phase shift line 44 is connected to a second end of an input-side coil 801 of the transformer 80.

The phase shift lines 41 and 42 constitute a second phase shift circuit and are connected between the signal input terminal 120 and the input end of the carrier amplifier 11. With the above configuration, the phase shift lines 41 and 42 (the second phase shift circuit) can invert the phase of the output signal of the auxiliary amplifier 22 at the signal output terminal 110 with respect to the phase of the output signal of the peak amplifier 21 at the signal output terminal 110.

Each of the phase shift lines 41 and 44 is not necessarily configured to delay the phase of an input radio frequency signal in the band A exactly by 90° and may be any type of circuit that delays the phase of a radio frequency signal in the band A by a degree within 90°±20°. Also, the phase shift line 42 is not necessarily configured to advance the phase of an input radio frequency signal in the band A exactly by 90° and may be any type of circuit that advances the phase of an input radio frequency signal in the band A by a degree within 90°±20°.

The transformer 80 includes the input-side coil 801 and an output-side coil 802 that are electromagnetically coupled to each other. A first end of the input-side coil 801 is connected to the output end of the carrier amplifier 11, and a second end of the input-side coil 801 is connected to the second end of the phase shift line 44. A first end of the output-side coil 802 is connected to the signal output terminal 110, and a second end of the output-side coil 802 is connected to a ground.

In the amplifier circuit 10A according to this example, because a path having the auxiliary amplifier 22 and the phase shift line 42 is provided, a signal (a peak signal) leaking directly from the peak amplifier 21 to the signal output terminal 110 is offset by a signal (a peak auxiliary signal) transmitted through the path. This in turn makes it possible to reduce the distortion of an output signal resulting from the operation of the peak amplifier 21.

A state of the amplifier circuit 10A according to this example is described in detail below with reference to FIG. 4.

As illustrated in FIG. 4, a radio frequency main signal is first input from the signal input terminal 120. Here, it is assumed that the phase of the radio frequency main signal is 0° at a node n1 on a path connecting the signal input terminal 120 to the splitter 50. The power of the radio frequency main signal is distributed by the splitter 50 to a carrier main signal output to the carrier amplifier 11 and a peak signal and a peak auxiliary signal output to the peak amplifier 21 and the auxiliary amplifier 22. At a node n2 on a path connecting the splitter 50 to the carrier amplifier 11, the phase of the carrier main signal is unchanged at 0°. On the other hand, at a node n4 on a path connecting the phase shift line 41 to the peak amplifier 21 and the auxiliary amplifier 22, the phases of the peak signal and the peak auxiliary signal are delayed by 90° by the phase shift line 41 to become −90°.

Next, the phase of the carrier main signal is inverted by the carrier amplifier 11 to become −180° at a node n3 corresponding to the first end of the input-side coil 801. On the other hand, the phase of the peak signal is inverted by the peak amplifier 21 to become −270° at a node n6 corresponding to the output end of the peak amplifier 21 and is delayed by 90° by the phase shift line 44 to become 0° at a node n8 corresponding to the second end of the input-side coil 801. Furthermore, the peak signal at the node n8 is transmitted from the second end of the input-side coil 801 to the first end of the output-side coil, and the phase of the peak signal is thereby inverted to become −180° at a node n9 corresponding to the first end of the output-side coil 802. Also, the phase of the peak auxiliary signal is inverted by the auxiliary amplifier 22 to become −270° at a node n5 corresponding to the output end of the auxiliary amplifier 22 and is advanced by 90° by the phase shift line 42 to become −180° at a node n7 corresponding to the input end of the carrier amplifier 11. Furthermore, the phase of the peak auxiliary signal is inverted by the carrier amplifier 11 to become 0° at the node n3. Then, the peak auxiliary signal at the node n3 is transmitted from the first end of the input-side coil 801 to the first end of the output-side coil. Therefore, the phase of the peak auxiliary signal is not inverted and is 0° at the node n9.

Here, because the phases of the peak signal and the peak auxiliary signal are opposite to each other at the node n9, the peak signal and the peak auxiliary signal substantially offset each other at the node n9. This makes it possible to prevent a part of the output signal of the peak amplifier 21 from leaking to the signal output terminal 110 by itself. Thus, it is possible to provide the amplifier circuit 10A having improved power efficiency and configured to improve gain linearity and reduce signal distortion.

Here, the gain of the auxiliary amplifier 22 is determined such that the amplitudes of the peak signal and the peak auxiliary signal become substantially the same at the node n9. In this example, the gain of the auxiliary amplifier 22 is preferably lower than the gain of the peak amplifier 21. This makes it possible to make the amplitude of the peak signal reaching the node n9 after being amplified by the peak amplifier 21 substantially the same as the amplitude of the peak auxiliary signal reaching the node n9 after being amplified by the auxiliary amplifier 22 and the carrier amplifier 11.

Also, the amplifier circuit 10A may further include an attenuator connected between the output end of the auxiliary amplifier 22 and a connection point between the input end of the carrier amplifier 11 and the phase shift line 42. This makes it possible to adjust the amplitude of the peak auxiliary signal. The attenuator may be configured such that its attenuation rate is variable according to the power and the frequency of a radio frequency signal input to the amplifier circuit 10A.

In the amplifier circuit 10A according to this example, the first end of the phase shift line 42 may be connected to the output end of the auxiliary amplifier 22, and the second end of the phase shift line 42 may be connected to the output end of the carrier amplifier 11. That is, the second phase shift circuit constituted by the third phase shift circuit and the fourth phase shift circuit may be connected between the signal input terminal 120 and the output end of the carrier amplifier 11. In this case, because the peak auxiliary signal does not pass through the carrier amplifier 11 and merges with the carrier main signal at the output end of the carrier amplifier 11, the phase shift line 42 needs to be configured to delay an input signal by 90°, and the gain of the auxiliary amplifier 22 needs to be set higher. This makes it possible to set the phases of the peak signal and the peak auxiliary signal to be opposite to each other at the node n9. As a result, the peak signal and the peak auxiliary signal substantially offset each other at the node n9. This in turn makes it possible to prevent the output signal of the peak amplifier 21 from leaking to the signal output terminal 110 by itself and thereby makes it possible to reduce signal distortion.

Also, in the amplifier circuit 10A according to this example, the peak amplifier 21 and the auxiliary amplifier 22 may be implemented by one peak amplifier and a power splitter connected to the output end of the peak amplifier.

### 3 Circuit Configuration of Amplifier Circuit 10B According to Third Example

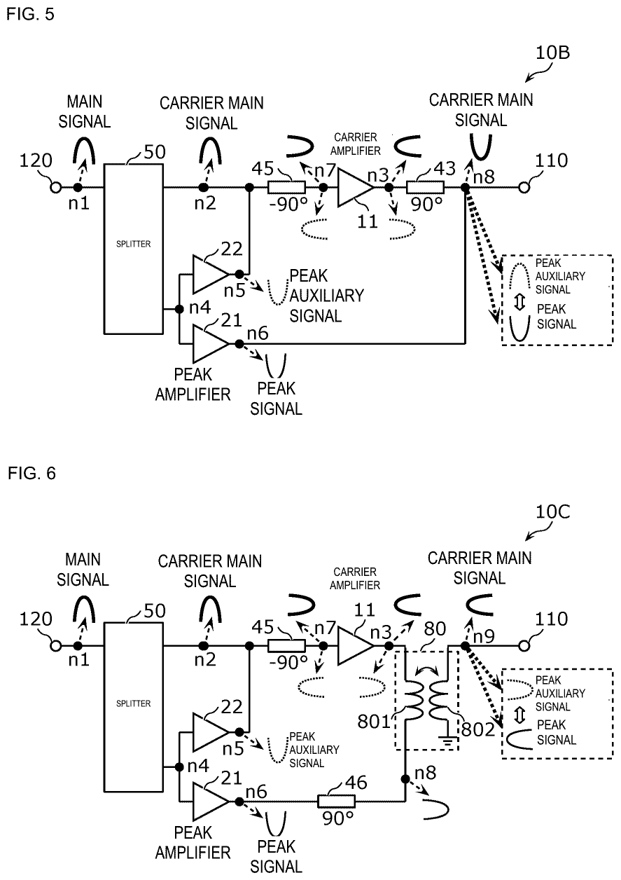

A circuit configuration of an amplifier circuit 10B according to a third example of the present exemplary embodiment is described with reference to FIG. 5. FIG. 5 is a circuit diagram of the amplifier circuit 10B according to the third example. As illustrated in FIG. 5, the amplifier circuit 10B includes a signal input terminal 120, a signal output terminal 110, a carrier amplifier 11, a peak amplifier 21, an auxiliary amplifier 22, phase shift lines 43 and 45, and a splitter 50. The amplifier circuit 10B according to this example differs from the amplifier circuit 10 according to the first example in that the phase shift line 45 is provided in place of the phase shift lines 41 and 42. Below, descriptions of configurations of the amplifier circuit 10B of this example identical to those of the amplifier circuit 10 of the first example are omitted, and different configurations are mainly described.

The input end of the carrier amplifier 11 is connected to the signal input terminal 120 via the splitter 50 and the phase shift line 45, and the output end of the carrier amplifier 11 is connected to the signal output terminal 110 via the phase shift line 43.

The input end of the peak amplifier 21 is connected to the signal input terminal 120 via the splitter 50, and the output end of the peak amplifier 21 is connected to the signal output terminal 110.

The input end of the auxiliary amplifier 22 is connected to the signal input terminal 120 via the splitter 50, and the output end of the auxiliary amplifier 22 is connected to the input end of the carrier amplifier 11 via the phase shift line 45.

The bias voltage applied to the auxiliary amplifier 22 is preferably the same as the bias voltage applied to the peak amplifier 21. Furthermore, it is preferable that the power supply voltage applied to the auxiliary amplifier 22 is the same as the power supply voltage applied to the peak amplifier 21, and the operating point of the auxiliary amplifier 22 is the same as the operating point of the peak amplifier 21. This makes it possible to make the behavior of the output signal of the auxiliary amplifier 22 conform to the behavior of the output signal of the peak amplifier 21.

The phase shift line 45 is an example of a second phase shift circuit, advances the phase of a radio frequency signal input from its first end by 90° (a quarter wavelength) (or delays the radio frequency signal by 270°), and outputs the phase-advanced radio frequency signal from its second end. The phase shift line 45 (the second phase shift circuit) does not have to be in the form of a phase shift line and may be, for example, a capacitor, or a high-pass filter including a capacitor and an inductor, that is disposed in series in a path connecting the output end of the auxiliary amplifier 22 to the input end of the carrier amplifier 11. The first end of the phase shift line 45 is connected to a connection point between the signal input terminal 120 (the splitter 50) and the output end of the auxiliary amplifier 22, and the second end of the phase shift line 45 is connected to the input end of the carrier amplifier 11.

The phase shift line 45 is connected between the signal input terminal 120 and the input end of the carrier amplifier 11 and is configured to invert the phase of the output signal of the auxiliary amplifier 22 at the signal output terminal 110 with respect to the phase of the output signal of the peak amplifier 21 at the signal output terminal 110.

Also, the phase shift line 45 is not necessarily configured to advance the phase of an input radio frequency signal in the band A exactly by 90° and may be any type of circuit that advances the phase of an input radio frequency signal in the band A by a degree within 90°±20°.

The splitter 50 is an example of a power splitter and is connected between the signal input terminal 120 and the input ends of the carrier amplifier 11, the peak amplifier 21, and the auxiliary amplifier 22. The splitter 50 includes a first terminal, a second terminal, and a third terminal, the first terminal is connected to the signal input terminal 120, the second terminal is connected to the input end of the carrier amplifier 11, and the third terminal is connected to the input ends of the peak amplifier 21 and the auxiliary amplifier 22.

In the amplifier circuit 10B according to this example, because a path having the auxiliary amplifier 22 and the phase shift line 45 is provided, a signal (a peak signal) leaking directly from the peak amplifier 21 to the signal output terminal 110 is offset by a signal (a peak auxiliary signal) transmitted through the path. This in turn makes it possible to reduce the distortion of an output signal resulting from the operation of the peak amplifier 21.

A state of the amplifier circuit 10B according to this example is described in detail below with reference to FIG. 5.

As illustrated in FIG. 5, a radio frequency main signal is first input from the signal input terminal 120. Here, it is assumed that the phase of the radio frequency main signal is 0° at a node n1 on a path connecting the signal input terminal 120 to the splitter 50. The power of the radio frequency main signal is distributed by the splitter 50 to a carrier main signal output to the carrier amplifier 11 and a peak signal and a peak auxiliary signal output to the peak amplifier 21 and the auxiliary amplifier 22. The phase of the carrier main signal is unchanged at 0° at a node n2 on a path connecting the splitter 50 to the phase shift line 45 and is advanced by 90° by the phase shift line 45 to become +90° at a node n7 corresponding to the input end of the carrier amplifier 11.

On the other hand, the phase of the peak signal is inverted by the peak amplifier 21 to become −180° at a node n6 corresponding to the output end of the peak amplifier 21 and is −180° at a node n8 connecting the output end of the peak amplifier 21 to the phase shift line 43. Also, the phase of the peak auxiliary signal is inverted by the auxiliary amplifier 22 to become −180° at a node n5 corresponding to the output end of the auxiliary amplifier 22 and is advanced by 90° by the phase shift line 45 to become −90° at the node n7. Furthermore, the phase of the peak auxiliary signal is inverted by the carrier amplifier 11 to become +90° at a node n3 corresponding to the output end of the carrier amplifier 11 and is delayed by 90° by the phase shift line 43 to become 0° at the node n8. Here, because the phases of the peak signal and the peak auxiliary signal are opposite to each other at the node n8, the peak signal and the peak auxiliary signal substantially offset each other at the node n8.

This makes it possible to prevent a part of the output signal of the peak amplifier 21 from leaking to the signal output terminal 110 by itself. Thus, it is possible to provide the amplifier circuit 10B having improved power efficiency and configured to improve gain linearity and reduce signal distortion.

Here, the gain of the auxiliary amplifier 22 is determined such that the amplitudes of the peak signal and the peak auxiliary signal become substantially the same at the node n8. In this example, the gain of the auxiliary amplifier 22 is preferably lower than the gain of the peak amplifier 21. This makes it possible to make the amplitude of the peak signal reaching the node n8 after being amplified by the peak amplifier 21 substantially the same as the amplitude of the peak auxiliary signal reaching the node n8 after being amplified by the auxiliary amplifier 22 and the carrier amplifier 11.

Also, in the amplifier circuit 10B according to this example, the peak amplifier 21 and the auxiliary amplifier 22 may be implemented by one peak amplifier and a power splitter connected to the output end of the peak amplifier.

### 4 Circuit Configuration of Amplifier Circuit 10C According to Fourth Example

A circuit configuration of an amplifier circuit 10C according to a fourth example of the present exemplary embodiment is described with reference to FIG. 6. FIG. 6 is a circuit diagram of the amplifier circuit 10C according to the fourth example. As illustrated in FIG. 6, the amplifier circuit 10C includes a signal input terminal 120, a signal output terminal 110, a carrier amplifier 11, a peak amplifier 21, an auxiliary amplifier 22, phase shift lines 45 and 46, a splitter 50, and a transformer 80. The amplifier circuit 10C according to this example differs from the amplifier circuit 10B according to the third example in that a phase shift line 46 is provided in place of the phase shift line 43 and that the transformer 80 is added. Below, descriptions of configurations of the amplifier circuit 10C of this example identical to those of the amplifier circuit 10B of the third example are omitted, and different configurations are mainly described.

The input end of the carrier amplifier 11 is connected to the signal input terminal 120 via the splitter 50, and the output end of the carrier amplifier 11 is connected to the signal output terminal 110 via the transformer 80.

The input end of the peak amplifier 21 is connected to the signal input terminal 120 via the splitter 50, and the output end of the peak amplifier 21 is connected to the signal output terminal 110 via the transformer 80 and the phase shift line 46.

The input end of the auxiliary amplifier 22 is connected to the signal input terminal 120 via the splitter 50, and the output end of the auxiliary amplifier 22 is connected to the input end of the carrier amplifier 11 via the phase shift line 45.

The bias voltage applied to the auxiliary amplifier 22 is preferably the same as the bias voltage applied to the peak amplifier 21. Furthermore, it is preferable that the power supply voltage applied to the auxiliary amplifier 22 is the same as the power supply voltage applied to the peak amplifier 21, and the operating point of the auxiliary amplifier 22 is the same as the operating point of the peak amplifier 21. This makes it possible to make the behavior of the output signal of the auxiliary amplifier 22 conform to the behavior of the output signal of the peak amplifier 21.

The phase shift line 46 is an example of a first phase shift circuit and is, for example a quarter wavelength transmission line. The phase shift line 46 delays the phase of a radio frequency signal input from its first end by 90° (a quarter wavelength) and outputs the phase-delayed radio frequency signal from its second end. The phase shift line 46 (the first phase shift circuit) does not have to be in the form of a phase shift line. For example, the phase shift line 46 may be an inductor, or a low pass filter including an inductor and a capacitor, that is disposed in series in a path connecting the peak amplifier 21 to the signal output terminal 110. The first end of the phase shift line 46 is connected to the output end of the peak amplifier 21, and the second end of the phase shift line 46 is connected to a second end of an input-side coil 801 of the transformer 80.

The phase shift line 45 is connected between the signal input terminal 120 and the input end of the carrier amplifier 11 and is configured to invert the phase of the output signal of the auxiliary amplifier 22 at the signal output terminal 110 with respect to the phase of the output signal of the peak amplifier 21 at the signal output terminal 110.

The transformer 80 includes the input-side coil 801 and an output-side coil 802 that are electromagnetically coupled to each other. A first end of the input-side coil 801 is connected to the output end of the carrier amplifier 11, and a second end of the input-side coil 801 is connected to the second end of the phase shift line 46. A first end of the output-side coil 802 is connected to the signal output terminal 110, and a second end of the output-side coil 802 is connected to a ground.

In the amplifier circuit 10C according to this example, because a path having the auxiliary amplifier 22 and the phase shift line 45 is provided, a signal (a peak signal) leaking directly from the peak amplifier 21 to the signal output terminal 110 is offset by a signal (a peak auxiliary signal) transmitted through the path. This in turn makes it possible to reduce the distortion of an output signal resulting from the operation of the peak amplifier 21.

A state of the amplifier circuit 10C according to this example is described in detail below with reference to FIG. 6.

As illustrated in FIG. 6, a radio frequency main signal is first input from the signal input terminal 120. Here, it is assumed that the phase of the radio frequency main signal is 0° at a node n1 on a path connecting the signal input terminal 120 to the splitter 50. The power of the radio frequency main signal is distributed by the splitter 50 to a carrier main signal output to the carrier amplifier 11 and a peak signal and a peak auxiliary signal output to the peak amplifier 21 and the auxiliary amplifier 22. The phase of the carrier main signal is unchanged at 0° at a node n2 on a path connecting the splitter 50 to the phase shift line 45 and is advanced by 90° by the phase shift line 45 to become +90° at a node n7 corresponding to the input end of the carrier amplifier 11.

On the other hand, the phase of the peak signal is inverted by the peak amplifier 21 to become −180° at a node n6 corresponding to the output end of the peak amplifier 21 and is shifted by the phase shift line 46 to become −270° at a node n8 corresponding to the second end of the input-side coil 801. Also, the phase of the peak auxiliary signal is inverted by the auxiliary amplifier 22 to become −180° at a node n5 corresponding to the output end of the auxiliary amplifier 22 and is advanced by 90° by the phase shift line 45 to become −90° at a node n7. Furthermore, the phase of the peak auxiliary signal is inverted by the carrier amplifier 11 to become +90° at a node n3 corresponding to the output end of the carrier amplifier 11.

Next, the peak signal at the node n8 is transmitted from the second end of the input-side coil 801 to the first end of the output-side coil, and the phase of the peak signal is thereby inverted to become −90° at a node n9 corresponding to the first end of the output-side coil 802. Also, the peak auxiliary signal is transmitted from the first end of the input-side coil 801 to the first end of the output-side coil. Therefore, the phase of the peak auxiliary signal is not inverted and is +90° at the node n9. Here, because the phases of the peak signal and the peak auxiliary signal are opposite to each other at the node n9, the peak signal and the peak auxiliary signal substantially offset each other at the node n9.

This makes it possible to prevent a part of the output signal of the peak amplifier 21 from leaking to the signal output terminal 110 by itself. Thus, it is possible to provide the amplifier circuit 10C having improved power efficiency and configured to improve gain linearity and reduce signal distortion.

Here, the gain of the auxiliary amplifier 22 is determined such that the amplitudes of the peak signal and the peak auxiliary signal become substantially the same at the node n9. In this example, the gain of the auxiliary amplifier 22 is preferably lower than the gain of the peak amplifier 21. This makes it possible to make the amplitude of the peak signal reaching the node n9 after being amplified by the peak amplifier 21 substantially the same as the amplitude of the peak auxiliary signal reaching the node n9 after being amplified by the auxiliary amplifier 22 and the carrier amplifier 11.

Also, the amplifier circuit 10C may further include an attenuator connected between the output end of the auxiliary amplifier 22 and a connection point between the signal input terminal 120 (the splitter 50) and the output end of the auxiliary amplifier 22. This makes it possible to adjust the amplitude of the peak auxiliary signal. The attenuator may be configured such that its attenuation rate is variable according to the power and the frequency of a radio frequency signal input to the amplifier circuit 10C.

Also, in the amplifier circuit 10C according to this example, the peak amplifier 21 and the auxiliary amplifier 22 may be implemented by one peak amplifier and a power splitter connected to the output end of the peak amplifier.

### 5 Circuit Configuration of Amplifier Circuit 10D According to Fifth Example

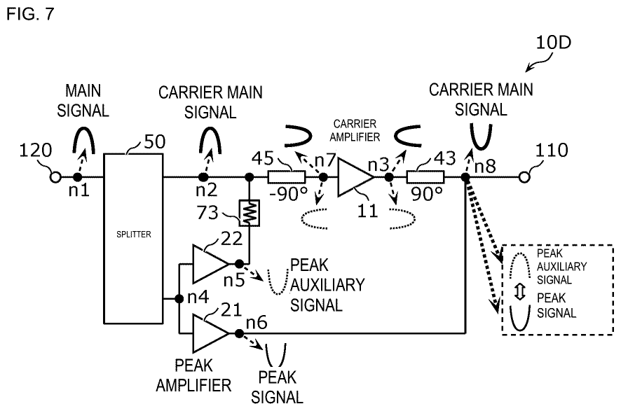

A circuit configuration of an amplifier circuit 10D according to a fifth example of the present exemplary embodiment is described with reference to FIG. 7. FIG. 7 is a circuit diagram of the amplifier circuit 10D according to the fifth example. As illustrated in FIG. 7, the amplifier circuit 10D includes a signal input terminal 120, a signal output terminal 110, a carrier amplifier 11, a peak amplifier 21, an auxiliary amplifier 22, phase shift lines 43 and 45, a splitter 50, and an attenuator 73. The amplifier circuit 10D according to this example differs from the amplifier circuit 10B according to the third example in that the attenuator 73 is added. Below, descriptions of configurations of the amplifier circuit 10D of this example identical to those of the amplifier circuit 10B of the third example are omitted, and different configurations are mainly described.

The attenuator 73 is connected between the output end of the auxiliary amplifier 22 and a connection point between the signal input terminal 120 (the splitter 50) and the output end of the auxiliary amplifier 22.

The input end of the carrier amplifier 11 is connected to the signal input terminal 120 via the splitter 50 and the phase shift line 45, and the output end of the carrier amplifier 11 is connected to the signal output terminal 110 via the phase shift line 43.

The input end of the peak amplifier 21 is connected to the signal input terminal 120 via the splitter 50, and the output end of the peak amplifier 21 is connected to the signal output terminal 110.

The input end of the auxiliary amplifier 22 is connected to the signal input terminal 120 via the splitter 50, and the output end of the auxiliary amplifier 22 is connected to the input end of the carrier amplifier 11 via the phase shift line 45 and the attenuator 73.

A first end of the phase shift line 45 is connected to a connection point between the signal input terminal 120 (the splitter 50) and the attenuator, and a second end of the phase shift line 45 is connected to the input end of the carrier amplifier 11.

In the amplifier circuit 10D with the above configuration, because a path having the auxiliary amplifier 22, the attenuator 73, and the phase shift line 45 is provided, a signal (a peak signal) leaking directly from the peak amplifier 21 to the signal output terminal 110 is offset by a signal (a peak auxiliary signal) transmitted through the path. This in turn makes it possible to reduce the distortion of an output signal resulting from the operation of the peak amplifier 21. Also, providing the attenuator 73 makes it possible to adjust the amplitude of the peak auxiliary signal and thereby makes it possible to accurately offset the peak signal with the peak auxiliary signal. The attenuator 73 may be configured such that its attenuation rate is variable according to the power and the frequency of a radio frequency signal input to the amplifier circuit 10D.

### 6 Effects

As described above, each of the amplifier circuit 10 according to the first example, the amplifier circuit 10A according to the second example, the amplifier circuit 10B according to the third example, the amplifier circuit 10C according to the fourth example, and the amplifier circuit 10D according to the fifth example includes the signal input terminal 120, the signal output terminal 110, the carrier amplifier 11 connected between the signal input terminal 120 and the signal output terminal 110, the peak amplifier 21 connected between the signal input terminal 120 and the signal output terminal 110, the first phase shift circuit connected between the carrier amplifier 11 and the signal output terminal 110 or between the peak amplifier 21 and the signal output terminal 110, the auxiliary amplifier 22 connected between the signal input terminal 120 and the input end or the output end of the carrier amplifier 11, and the second phase shift circuit that is connected between the signal input terminal 120 and the input end or the output end of the carrier amplifier 11 and configured to invert the phase the output signal of the auxiliary amplifier 22 at the signal output terminal 110 with respect to the phase of the output signal of the peak amplifier 21 at the signal output terminal 110.

With this configuration, because a path connecting the auxiliary amplifier 22 to the signal output terminal 110 is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuits 10, 10A, 10B, 10C, and 10D having improved power efficiency and configured to improve gain linearity and reduce signal distortion.

Also, for example, in the amplifier circuit 10, the second phase shift circuit includes the phase shift line 41 (the third phase shift circuit) connected between the signal input terminal 120 and the connection point between the input end of the peak amplifier 21 and the input end of the auxiliary amplifier 22 and the phase shift line 42 (the fourth phase shift circuit) connected between the output end of the auxiliary amplifier 22 and the input end of the carrier amplifier 11, the first end of the phase shift line 43 (the first phase shift circuit) is connected to the output end of the carrier amplifier 11, and the second end of the phase shift line 43 (the first phase shift circuit) is connected to the connection point between the output end of the peak amplifier 21 and the signal output terminal 110.

With this configuration, because a path having the auxiliary amplifier 22 and the phase shift line 42 is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuit 10 having improved power efficiency and configured to improve gain linearity and reduce signal distortion.

Also, for example, the amplifier circuit 10A includes the transformer 80 including the input-side coil 801 and the output-side coil 802, the first end of the phase shift line 44 (the first phase shift circuit) is connected to the output end of the peak amplifier 21, the first end of the input-side coil 801 is connected to the output end of the carrier amplifier, the second end of the input-side coil 801 is connected to the second end of the phase shift line 44 (the first phase shift circuit), the first end of the output-side coil 802 is connected to the signal output terminal 110, the second end of the output-side coil 802 is connected to the ground, and the second phase shift circuit includes the phase shift line 41 (the third phase shift circuit) connected between the signal input terminal 120 and the connection point between the input end of the peak amplifier 21 and the input end of the auxiliary amplifier 22 and the phase shift line 42 (the fourth phase shift circuit) connected between the output end of the auxiliary amplifier 22 and the input end of the carrier amplifier 11.

With this configuration, because a path having the auxiliary amplifier 22 and the phase shift line 42 is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuit 10A having improved power efficiency and configured to improve gain linearity and reduce signal distortion.

Also, for example, in the amplifier circuits 10 and 10A, each of the carrier amplifier 11, the peak amplifier 21, and the auxiliary amplifier 22 is an inverting amplifier, the first phase shift circuit is a phase shift line that delays an input signal by 90°, the third phase shift circuit is a phase shift line that delays an input signal by 90°, and the fourth phase shift circuit is a phase shift line that advances an input signal by 90°.

With this configuration, the amplifier circuit 10 with the first phase shift circuit functions as a current-combining Doherty amplifier circuit, the amplifier circuit 10A with the first phase shift circuit functions as a voltage-combining Doherty amplifier circuit, and the second phase shift circuit makes it possible to accurately offset the peak signal leaking to the signal output terminal 110 by the peak auxiliary signal.

Also, for example, each of the amplifier circuits 10 and 10A further includes an attenuator connected between the output end of the auxiliary amplifier 22 and a connection point between the input end of the carrier amplifier 11 and the fourth phase shift circuit.

With this configuration, because the attenuator is provided in a path having the auxiliary amplifier 22 and the fourth phase shift circuit, it is possible to adjust the amplitude of the peak auxiliary signal. This in turn makes it possible to accurately offset the peak signal by the peak auxiliary signal.

Also, for example, in the amplifier circuits 10 and 10A, the gain of the auxiliary amplifier 22 is lower than the gain of the peak amplifier 21.

This makes it possible to make the amplitude of the peak signal reaching the signal output terminal 110 after being amplified by the peak amplifier 21 substantially the same as the amplitude of the peak auxiliary signal reaching the signal output terminal 110 after being amplified by the auxiliary amplifier 22 and the carrier amplifier 11.

Also, for example, in the amplifier circuit 10B, the phase shift line 45 (the second phase shift circuit) is connected between the input end of the carrier amplifier 11 and the connection point between the signal input terminal 120 and the output end of the auxiliary amplifier 22, the first end of the phase shift line 43 (the first phase shift circuit) is connected to the output end of the carrier amplifier 11, and the second end of the phase shift line 43 (the first phase shift circuit) is connected to the connection point between the output end of the peak amplifier 21 and the signal output terminal 110.

With this configuration, because a path having the auxiliary amplifier 22 and the phase shift line 45 is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuit 10B having improved power efficiency and configured to improve gain linearity and reduce signal distortion.

Also, for example, the amplifier circuit 10C further includes the transformer 80 including the input-side coil 801 and the output-side coil 802, the first end of the phase shift line 46 (the first phase shift circuit) is connected to the output end of the peak amplifier 21, the first end of the input-side coil 801 is connected to the output end of the carrier amplifier 11, the second end of the input-side coil 801 is connected to the second end of the phase shift line 46 (the first phase shift circuit), the first end of the output-side coil 802 is connected to the signal output terminal 110, the second end of the output-side coil 802 is connected to the ground, the phase shift line 45 (the second phase shift circuit) is connected between the input end of the carrier amplifier 11 and the connection point between the signal input terminal 120 and the output end of the auxiliary amplifier 22.

With this configuration, because a path having the auxiliary amplifier 22 and the phase shift line 45 is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuit 10C having improved power efficiency and configured to improve gain linearity and reduce signal distortion.

Also, for example, in the amplifier circuits 10B and 10C, each of the carrier amplifier 11, the peak amplifier 21, and the auxiliary amplifier 22 is an inverting amplifier, the first phase shift circuit is a phase shift line that delays an input signal by 90°, and the second phase shift circuit is a phase shift line that advances an input signal by 90°.

With this configuration, the amplifier circuit 10B with the first phase shift circuit functions as a current-combining Doherty amplifier circuit, the amplifier circuit 10C with the first phase shift circuit functions as a voltage-combining Doherty amplifier circuit, and the second phase shift circuit makes it possible to accurately offset the peak signal leaking to the signal output terminal 110 by the peak auxiliary signal.

Also, each of the amplifier circuits 10B and 10C further includes an attenuator connected between the output end of the auxiliary amplifier 22 and a connection point between the signal input terminal 120 and the output end of the auxiliary amplifier 22.

With this configuration, because the attenuator is provided in a path having the auxiliary amplifier 22 and the second phase shift circuit, it is possible to adjust the amplitude of the peak auxiliary signal. This in turn makes it possible to accurately offset the peak signal by the peak auxiliary signal.

Also, for example, in the amplifier circuits 10B and 10C, the gain of the auxiliary amplifier 22 is lower than the gain of the peak amplifier 21.

This makes it possible to make the amplitude of the peak signal reaching the signal output terminal 110 after being amplified by the peak amplifier 21 substantially the same as the amplitude of the peak auxiliary signal reaching the signal output terminal 110 after being amplified by the auxiliary amplifier 22 and the carrier amplifier 11.

Also, for example, each of the amplifier circuits 10, 10A, 10B, 10C, and 10D further includes the splitter 50 connected between the signal input terminal 120 and the input ends of the carrier amplifier 11, the peak amplifier 21, and the auxiliary amplifier 22.

This configuration makes it possible to distribute the power of a radio frequency signal input to the signal input terminal 120 between two radio frequency signals at a predetermined distribution ratio, to output one of the radio frequency signals to the carrier amplifier 11, and to output the other one of the radio frequency signals to the peak amplifier 21 and the auxiliary amplifier 22.

Also, for example, in the amplifier circuits 10, 10A, 10B, 10C, and 10D, the bias voltage applied to the auxiliary amplifier 22 is the same as the bias voltage applied to the peak amplifier 21.

This makes it possible to make the behavior of the output signal of the auxiliary amplifier 22 conform to the behavior of the output signal of the peak amplifier 21 and thereby makes it possible to accurately offset the peak signal leaking to the signal output terminal 110 by the peak auxiliary signal.

The amplifier circuit 10B according to the third example includes the signal input terminal 120, the signal output terminal 110, the carrier amplifier 11 connected between the signal input terminal 120 and the signal output terminal 110, the peak amplifier 21 connected between the signal input terminal 120 and the signal output terminal 110, the first phase shift circuit connected between the output end of the carrier amplifier 11 and the signal output terminal 110, the auxiliary amplifier 22 connected between the signal input terminal 120 and the input end of the carrier amplifier 11, and the second phase shift circuit connected between the input end of the carrier amplifier 11 and the connection point between the signal input terminal 120 and the output end of the auxiliary amplifier 22.

With this configuration, because a path having the auxiliary amplifier 22 and the second phase shift circuit is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuit 10B having improved power efficiency and configured to improve gain linearity and reduce signal distortion.

The amplifier circuit 10C according to the fourth example includes the signal input terminal 120, the signal output terminal 110, the carrier amplifier 11 connected between the signal input terminal 120 and the signal output terminal 110, the peak amplifier 21 connected between the signal input terminal 120 and the signal output terminal 110, the first phase shift circuit, the second phase shift circuit, the auxiliary amplifier 22 connected between the signal input terminal 120 and the input end of the carrier amplifier 11, and the transformer 80 including the input-side coil 801 and the output-side coil 802. The first end of the first phase shift circuit is connected to the output end of the peak amplifier 21, the first end of the input-side coil 801 is connected to the output end of the carrier amplifier 11, the second end of the input-side coil 801 is connected to the second end of the first phase shift circuit, the first end of the output-side coil 802 is connected to the signal output terminal 110, the second end of the output-side coil 802 is connected to the ground, the first end of the second phase shift circuit is connected to the connection point between the signal input terminal 120 and the output end of the auxiliary amplifier 22, and the second end of the second phase shift circuit is connected to the input end of the carrier amplifier 11.

With this configuration, because a path having the auxiliary amplifier 22 and the second phase shift circuit is provided, a signal leaking from the peak amplifier 21 to the signal output terminal 110 is offset by a signal transmitted through the path. This in turn makes it possible to reduce the distortion of an output signal resulting from the operation of the peak amplifier 21. Thus, it is possible to provide the amplifier circuit 10C having improved power efficiency and configured to improve gain linearity and reduce signal distortion.

### Other Exemplary Embodiments

Amplifier circuits according to the examples of the exemplary embodiment of the present disclosure are described above. However, the present disclosure is not limited to the above described examples. The present disclosure also includes other examples implemented by combining components in the above examples, variations obtained by applying various modifications conceivable by a person skilled in the art to the above examples within the scope of the present disclosure, and various devices including the above-described amplifier circuits.

Also, for example, in the amplifier circuits, the radio frequency circuits, and the communication devices according to the above examples, another component, such as a circuit element or a wire, may be inserted in a path connecting circuit elements and signal paths disclosed in the drawings.

Below, features of the amplifier circuits according to the above examples are described.
<1> An amplifier circuit includes an input terminal and an output terminal; a carrier amplifier connected between the input terminal and the output terminal; a peak amplifier connected between the input terminal and the output terminal; a first phase shift circuit connected between the carrier amplifier and the output terminal or between the peak amplifier and the output terminal; an auxiliary amplifier connected between the input terminal and an input end or an output end of the carrier amplifier; and a second phase shift circuit that is connected between the input terminal and the input end or the output end of the carrier amplifier and configured to invert a phase of an output signal of the auxiliary amplifier at the output terminal with respect to a phase of an output signal of the peak amplifier at the output terminal.
<2> The amplifier circuit described in <1>. The second phase shift circuit includes a third phase shift circuit connected between the input terminal and a connection point between an input end of the peak amplifier and an input end of the auxiliary amplifier, and a fourth phase shift circuit connected between an output end of the auxiliary amplifier and the input end of the carrier amplifier; a first end of the first phase shift circuit is connected to the output end of the carrier amplifier; and a second end of the first phase shift circuit is connected to a connection point between an output end of the peak amplifier and the output terminal.
<3> The amplifier circuit described in <1> further includes a transformer including an input-side coil and an output-side coil. A first end of the first phase shift circuit is connected to an output end of the peak amplifier; a first end of the input-side coil is connected to the output end of the carrier amplifier; a second end of the input-side coil is connected to a second end of the first phase shift circuit; a first end of the output-side coil is connected to the output terminal; a second end of the output-side coil is connected to a ground; and the second phase shift circuit includes a third phase shift circuit connected between the input terminal and a connection point between an input end of the peak amplifier and an input end of the auxiliary amplifier, and a fourth phase shift circuit connected between an output end of the auxiliary amplifier and the input end of the carrier amplifier.
<4> The amplifier circuit described in <2> or <3>. Each of the carrier amplifier, the peak amplifier, and the auxiliary amplifier is an inverting amplifier; the first phase shift circuit is a phase shift line that delays an input signal by 90°; the third phase shift circuit is a phase shift line that delays an input signal by 90°; and the fourth phase shift circuit is a phase shift line that advances an input signal by 90°.
<5> The amplifier circuit described in any one of <2> to <4> further includes an attenuator connected between the output end of the auxiliary amplifier and a connection point between the input end of the carrier amplifier and the fourth phase shift circuit.
<6> The amplifier circuit described in any one of <2> to <4>. The gain of the auxiliary amplifier is lower than the gain of the peak amplifier.
<7> The amplifier circuit described in <1>. The second phase shift circuit is connected between the input end of the carrier amplifier and a connection point between the input terminal and an output end of the auxiliary amplifier; and a first end of the first phase shift circuit is connected to the output end of the carrier amplifier, and a second end of the first phase shift circuit is connected to a connection point between an output end of the peak amplifier and the output terminal.
<8> The amplifier circuit described in <1> further includes a transformer including an input-side coil and an output-side coil. A first end of the first phase shift circuit is connected to an output end of the peak amplifier; a first end of the input-side coil is connected to the output end of the carrier amplifier; a second end of the input-side coil is connected to a second end of the first phase shift circuit; a first end of the output-side coil is connected to the output terminal; a second end of the output-side coil is connected to a ground; and the second phase shift circuit is connected between the input end of the carrier amplifier and a connection point between the input terminal and an output end of the auxiliary amplifier.
<9> The amplifier circuit described in <7> or <8>. Each of the carrier amplifier, the peak amplifier, and the auxiliary amplifier is an inverting amplifier; the first phase shift circuit is a phase shift line that delays an input signal by 90°; and the second phase shift circuit is a phase shift line that advances an input signal by 90°.
<10> The amplifier circuit described in any one of <7> to <9> further includes an attenuator connected between the output end of the auxiliary amplifier and a connection point between the input terminal and the output end of the auxiliary amplifier.
<11> The amplifier circuit described in any one of <7> to <9>. The gain of the auxiliary amplifier is lower than the gain of the peak amplifier.
<12> The amplifier circuit described in any one of <1> to <11> further includes a power splitter connected between the input terminal and input ends of the carrier amplifier, the peak amplifier, and the auxiliary amplifier.
<13> The amplifier circuit described in any one of <1> to <12>. A bias voltage applied to the auxiliary amplifier is equal to a bias voltage applied to the peak amplifier.
<14> An amplifier circuit includes an input terminal and an output terminal; a carrier amplifier connected between the input terminal and the output terminal; a peak amplifier connected between the input terminal and the output terminal; a first phase shift circuit connected between an output end of the carrier amplifier and the output terminal; an auxiliary amplifier connected between the input terminal and an input end of the carrier amplifier; and a second phase shift circuit connected between the input end of the carrier amplifier and a connection point between the input terminal and an output end of the auxiliary amplifier.
<15> An amplifier circuit includes an input terminal and an output terminal; a carrier amplifier connected between the input terminal and the output terminal; a peak amplifier connected between the input terminal and the output terminal; a first phase shift circuit and a second phase shift circuit; an auxiliary amplifier connected between the input terminal and an input end of the carrier amplifier; and a transformer including an input-side coil and an output-side coil. A first end of the first phase shift circuit is connected to an output end of the peak amplifier; a first end of the input-side coil is connected to an output end of the carrier amplifier; a second end of the input-side coil is connected to a second end of the first phase shift circuit; a first end of the output-side coil is connected to the output terminal; a second end of the output-side coil is connected to a ground; a first end of the second phase shift circuit is connected to a connection point between the input terminal and an output end of the auxiliary amplifier; and a second end of the second phase shift circuit is connected to the input end of the carrier amplifier.
<16> The amplifier circuit described in <14> or <15>. Each of the carrier amplifier, the peak amplifier, and the auxiliary amplifier is an inverting amplifier; the first phase shift circuit is a phase shift line that delays an input signal by 90°; and the second phase shift circuit is a phase shift line that advances an input signal by 90°.
<17> The amplifier circuit described in any one of <14> to <16> further includes a power splitter connected between the input terminal and input ends of the carrier amplifier, the peak amplifier, and the auxiliary amplifier.
<18> The amplifier circuit described in any one of <14> to <17>. A bias voltage applied to the auxiliary amplifier is equal to a bias voltage applied to the peak amplifier.

The present disclosure can be widely used for communication devices, such as mobile phones, as an amplifier circuit disposed in a multiband front-end unit.

What is claimed is:

1. An amplifier circuit comprising:
an input terminal and an output terminal;
a carrier amplifier connected between the input terminal and the output terminal;
a peak amplifier connected between the input terminal and the output terminal;
a first phase shift circuit connected between the carrier amplifier and the output terminal or between the peak amplifier and the output terminal;
an auxiliary amplifier connected between the input terminal and the carrier amplifier; and
a second phase shift circuit that is connected between the input terminal and the carrier amplifier.

2. The amplifier circuit according to claim 1, wherein
the second phase shift circuit includes
a third phase shift circuit connected between the input terminal and a connection point between an input end of the peak amplifier and an input end of the auxiliary amplifier, and
a fourth phase shift circuit connected between an output end of the auxiliary amplifier and an input end of the carrier amplifier;
a first end of the first phase shift circuit is connected to the output end of the carrier amplifier; and
a second end of the first phase shift circuit is connected to a connection point between an output end of the peak amplifier and the output terminal.

3. The amplifier circuit according to claim 1, further comprising:
a transformer including an input-side coil and an output-side coil, wherein
a first end of the first phase shift circuit is connected to an output end of the peak amplifier;
a first end of the input-side coil is connected to an output end of the carrier amplifier;
a second end of the input-side coil is connected to a second end of the first phase shift circuit;
a first end of the output-side coil is connected to the output terminal;
a second end of the output-side coil is connected to a ground; and
the second phase shift circuit includes
a third phase shift circuit connected between the input terminal and a connection point between an input end of the peak amplifier and an input end of the auxiliary amplifier, and
a fourth phase shift circuit connected between an output end of the auxiliary amplifier and an input end of the carrier amplifier.

4. The amplifier circuit according to claim 2, wherein
each of the carrier amplifier, the peak amplifier, and the auxiliary amplifier is an inverting amplifier;
the first phase shift circuit is a phase shift line that delays an input signal by 90°;
the third phase shift circuit is a phase shift line that delays an input signal by 90°; and
the fourth phase shift circuit is a phase shift line that advances an input signal by 90°.

5. The amplifier circuit according to claim 2, further comprising:
an attenuator connected between the output end of the auxiliary amplifier and a connection point between the input end of the carrier amplifier and the fourth phase shift circuit.

6. The amplifier circuit according to claim 2, wherein
a gain of the auxiliary amplifier is lower than a gain of the peak amplifier.

7. The amplifier circuit according to claim 1, wherein
the second phase shift circuit is connected between an input end of the carrier amplifier and a connection point between the input terminal and an output end of the auxiliary amplifier;
a first end of the first phase shift circuit is connected to the output end of the carrier amplifier; and
a second end of the first phase shift circuit is connected to a connection point between an output end of the peak amplifier and the output terminal.

8. The amplifier circuit according to claim 1, further comprising:
a transformer including an input-side coil and an output-side coil, wherein
a first end of the first phase shift circuit is connected to an output end of the peak amplifier;
a first end of the input-side coil is connected to an output end of the carrier amplifier;
a second end of the input-side coil is connected to a second end of the first phase shift circuit;
a first end of the output-side coil is connected to the output terminal;
a second end of the output-side coil is connected to a ground; and
the second phase shift circuit is connected between an input end of the carrier amplifier and a connection point between the input terminal and an output end of the auxiliary amplifier.

9. The amplifier circuit according to claim 7, wherein
each of the carrier amplifier, the peak amplifier, and the auxiliary amplifier is an inverting amplifier;
the first phase shift circuit is a phase shift line that delays an input signal by 90°; and
the second phase shift circuit is a phase shift line that advances an input signal by 90°.

10. The amplifier circuit according to claim 7, further comprising:
an attenuator connected between the output end of the auxiliary amplifier and a connection point between the input terminal and the output end of the auxiliary amplifier.

11. The amplifier circuit according to claim 7, wherein
a gain of the auxiliary amplifier is lower than a gain of the peak amplifier.

12. The amplifier circuit according to claim 1, further comprising:
a power splitter connected between the input terminal and input ends of the carrier amplifier, the peak amplifier, and the auxiliary amplifier.

13. The amplifier circuit according to claim 1, wherein
a bias voltage applied to the auxiliary amplifier is equal to a bias voltage applied to the peak amplifier.

14. The amplifier circuity according to claim 1, wherein the first phase shift circuit is connected between the peak amplifier and the output terminal.

15. The amplifier circuit according to claim 1, wherein the second phase shift circuit is configured to invert a phase of an output signal of the auxiliary amplifier at the output terminal with respect to a phase of an output signal of the peak amplifier at the output terminal.

16. An amplifier circuit comprising:
an input terminal and an output terminal;
a carrier amplifier connected between the input terminal and the output terminal;
a peak amplifier connected between the input terminal and the output terminal;
a first phase shift circuit connected between an output end of the carrier amplifier and the output terminal;
an auxiliary amplifier connected between the input terminal and an input end of the carrier amplifier; and
a second phase shift circuit connected between the input end of the carrier amplifier and a connection point between the input terminal and an output end of the auxiliary amplifier.

17. An amplifier circuit comprising:
an input terminal and an output terminal;
a carrier amplifier connected between the input terminal and the output terminal;
a peak amplifier connected between the input terminal and the output terminal;
a first phase shift circuit and a second phase shift circuit;
an auxiliary amplifier connected between the input terminal and an input end of the carrier amplifier; and
a transformer including an input-side coil and an output-side coil, wherein
a first end of the first phase shift circuit is connected to an output end of the peak amplifier;
a first end of the input-side coil is connected to an output end of the carrier amplifier;
a second end of the input-side coil is connected to a second end of the first phase shift circuit;
a first end of the output-side coil is connected to the output terminal;
a second end of the output-side coil is connected to a ground;
a first end of the second phase shift circuit is connected to a connection point between the input terminal and an output end of the auxiliary amplifier; and
a second end of the second phase shift circuit is connected to the input end of the carrier amplifier.

18. The amplifier circuit according to claim 17, wherein
each of the carrier amplifier, the peak amplifier, and the auxiliary amplifier is an inverting amplifier;
the first phase shift circuit is a phase shift line that delays an input signal by 90°; and
the second phase shift circuit is a phase shift line that advances an input signal by 90°.

19. The amplifier circuit according to claim 17, further comprising:
a power splitter connected between the input terminal and input ends of the carrier amplifier, the peak amplifier, and the auxiliary amplifier.

20. The amplifier circuit according to claim 17, wherein
a bias voltage applied to the auxiliary amplifier is equal to a bias voltage applied to the peak amplifier.
